(19) United States
(12) Patent Application Publication
(10) Pub. No.: US 2012/0000505 A1
(43) Pub. Date: Jan. 5, 2012

(54) THIN FILM PHOTOELECTRIC COVERSION MODULE

(75) Inventors: Chung-Pui CHAN, Hong Kong (HK); Hsieh-Hsin YEH, New Taipei City (TW)

(73) Assignee: Du Pont Apollo Limited, Hong Kong (HK)

(21) Appl. No.: 13/174,787

(22) Filed: Jul. 1, 2011

Related U.S. Application Data
(60) Provisional application No. 61/360,930, filed on Jul. 2, 2010.

(51) Int. Cl. H01L 31/05

(52) U.S. Cl. 136/244

(57) ABSTRACT

A thin film photoelectric conversion module is provided. The thin film photoelectric conversion module comprises a back electrode layer, a plurality of thin film photoelectric conversion cells, a front electrode layer and a plurality of opaque materials. The thin film photoelectric conversion cells are disposed on the back electrode layer in parallel to each other in a lengthwise direction. The front electrode layer is disposed on the thin film photoelectric conversion cells. Each of the opaque materials is disposed on a light-receiving surface of the front electrode layer and is traversing the thin film photoelectric conversion cells in a traversing direction to separate the thin film photoelectric conversion cells into a plurality of sub-arrays. In each of the sub-arrays, the thin film photoelectric conversion cells are connected in series along the traversing direction.

### RELATED APPLICATIONS

This application claims priority to U.S. Provisional Application Ser. No. 61/360,930, filed Jul. 2, 2010, which is herein incorporated by reference.

### BACKGROUND

1. Technical Field

The present disclosure relates to a photoelectric conversion apparatus. More particularly, the present disclosure relates to a thin film photoelectric conversion module.

2. Description of Related Art

A solar cell is a device that converts the energy of sunlight directly into electricity by the photovoltaic effect. In general, a thin film photoelectric conversion module used in a solar cell comprises a plurality of band-like thin film photoelectric conversion cells connected to each other in series.

When a stain, such as a leaf or a bird dropping, is attached to the light-receiving surface of parts of the thin film photoelectric conversion cell of the thin film photoelectric conversion module, the light to the particular cell is partially or entirely intercepted by the stain so as to decrease the photoelectric motive force. The decreased photoelectric motive force acts as a diode connected in series in the reverse direction to the direction of the power generation. As a result, the light-intercepted cell exhibits a very high resistance, leading to the marked reduction in the output of the entire module. Further, the current doesn't flow uniformly through the cell so as to bring about a local heating called a hot spot phenomenon.

In a conventional design, a laser-scribing process is performed to cut off the film photoelectric conversion cells and the electrode attached thereon to separate the cells and the electrode into a plurality of sub-arrays to prevent a large current from other sub-arrays flowing to the light-intercepted, i.e. the high resistance part. However, in such a design, when a part of the cells in one of the sub-array is not able to perform the photoelectric conversion mechanism, the whole sub-array fails to operate normally due to the abnormal part of the cells, reducing the efficiency of the entire module.

Accordingly, what is needed is a new design of the thin film photoelectric conversion module to maintain the efficiency even if the hot spot phenomenon occurs. The present disclosure addresses such a need.

### SUMMARY

An aspect of the present disclosure is to provide a thin film photoelectric conversion module. The thin film photoelectric conversion module comprises a back electrode layer, a plurality of thin film photoelectric conversion cells, a front electrode layer and a plurality of opaque materials. The thin film photoelectric conversion cells are disposed on the back electrode layer in parallel to each other in a lengthwise direction. The front electrode layer is disposed on the thin film photoelectric conversion cells. Each of the opaque materials is disposed on a light-receiving surface of the front electrode layer and is traversing the thin film photoelectric conversion cells in a traversing direction to separate the thin film photoelectric conversion cells into a plurality of sub-arrays. In each of the sub-arrays, the thin film photoelectric conversion cells are connected in series along the traversing direction.

Another aspect of the present disclosure is to provide a thin film photoelectric conversion module. The thin film photoelectric conversion module comprises a back electrode layer, a plurality of thin film photoelectric conversion cells, a front electrode layer and a plurality of semi-transparent materials. The thin film photoelectric conversion cells are disposed on the back electrode layer in parallel to each other in a lengthwise direction. The front electrode layer is disposed on the thin film photoelectric conversion cells. Each of the semi-transparent materials is disposed on a light-receiving surface of the front electrode layer and is traversing the thin film photoelectric conversion cells in a traversing direction to separate the thin film photoelectric conversion cells into a plurality of sub-arrays. In each of the sub-arrays, the thin film photoelectric conversion cells are connected in series along the traversing direction.

Yet another aspect of the present disclosure is to provide a thin film photoelectric conversion module. The thin film photoelectric conversion module comprises a back electrode layer, a plurality of thin film photoelectric conversion cells, a front electrode layer and a plurality of opaque materials or semi-transparent materials. The thin film photoelectric conversion cells are disposed on the back electrode layer in parallel to each other in a lengthwise direction. The front electrode layer is disposed on the thin film photoelectric conversion cells. Each of the opaque or semi-transparent materials is disposed between the front electrode layer and the thin film photoelectric conversion cells and is traversing the thin film photoelectric conversion cells in a traversing direction to separate the thin film photoelectric conversion cells into a plurality of sub-arrays. In each of the sub-arrays, the thin film photoelectric conversion cells are connected in series along the traversing direction.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments, with reference made to the accompanying drawings as follows:

FIG. 1 is a top view of a thin film photoelectric conversion module of an embodiment of the present disclosure;

FIG. 2 is a side view of the thin film photoelectric conversion module from the direction A in FIG. 1;

FIG. 3 is another side view of the thin film photoelectric conversion module from the direction B in FIG. 1;

FIG. 4 is a diagram of both the top view and the side view of the thin film photoelectric conversion module in FIG. 1 and FIG. 3;

FIG. 5 is a side view of the thin film photoelectric conversion module from the direction B in FIG. 1 in another embodiment of the present disclosure; and

FIG. 6 is a side view of the thin film photoelectric conversion module from the direction A in FIG. 1 in yet another embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

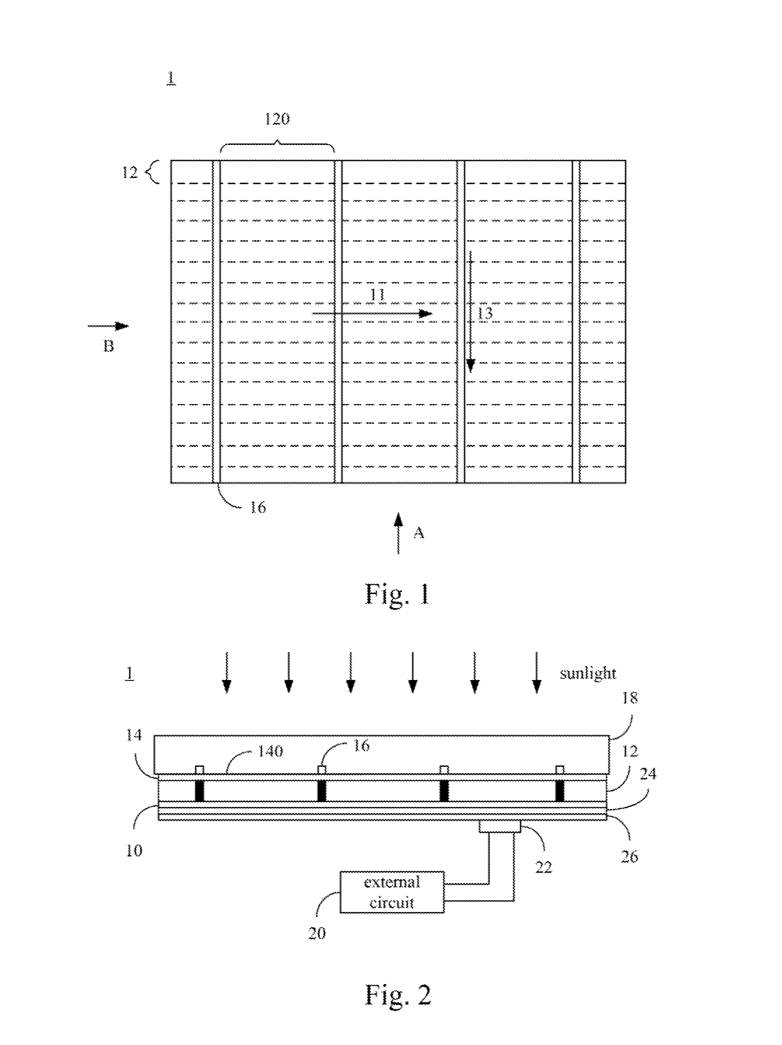

Please refer to FIG. 1 and FIG. 2 at the same time. FIG. 1 is a top view of a thin film photoelectric conversion module 1 of an embodiment of the present disclosure. FIG. 2 is a side view of the thin film photoelectric conversion module 1 from the direction A in FIG. 1.

The thin film photoelectric conversion module 1 comprises a back electrode layer 10, a plurality of thin film photoelectric conversion cells 12, a front electrode layer 14 and a plurality of opaque materials 16.

The back electrode layer 10 can be a transparent conducting layer or a metal electrode layer in different embodiments. The plurality of thin film photoelectric conversion cells 12 are disposed on the back electrode layer 10. The thin film photoelectric conversion cells 12 are in parallel to each other in a lengthwise direction 11. The front electrode layer 14 is disposed on the plurality of thin film photoelectric conversion cells 12, wherein the front electrode layer 14 has a light-receiving surface 140. The front electrode layer 14 is a transparent conducting layer such that the sunlight is able to pass through the front electrode layer 14.

In an embodiment, the front electrode layer 14 is a positive layer and the back electrode layer 10 is a negative layer. In other embodiments, the front electrode layer 14 can be a negative layer and the back electrode layer 10 can be a positive layer as well. Each of the thin film photoelectric conversion cells 12 comprises a P-I-N structure. In other words, in an embodiment, each of the thin film photoelectric conversion cells 12 comprises a p-type non-single crystalline silicon-based semiconductor layer connected to the front electrode layer 14, a non-single crystalline thin film photoelectric conversion layer and an n-type non-single crystalline silicon-based semiconductor layer connected to the back electrode layer 10 (not shown).

It's noticed that a p-i-n structure is usually used as opposed to an n-i-p structure. This is because the mobility of electrons in a-Si:H is roughly 1 or 2 orders of magnitude larger than that of holes, and thus the collection rate of electrons moving from the p- to n-type contact is better than holes moving from p- to n-type contact. Therefore, the p-type layer should be placed at the top where the light intensity is stronger, so that the majority of the charge carriers crossing the junction would be electrons.

A transparent substrate 18 is disposed on the light-receiving surface 140 of the front electrode layer 14. The plurality of opaque materials 16 are each disposed between the light-receiving surface 140 and the transparent substrate 18 in the present embodiment.

In the present embodiment, the opaque materials 16 are ribbon-like material traversing the plurality of thin film photoelectric conversion cells 12 in a traversing direction 13 substantially vertical to the lengthwise direction 11. It's noticed that the term “substantially” means that there can be a tolerable range of the actual position of the opaque materials 16. The opaque materials 16 are not necessary to be exactly 90 degrees relative to the lengthwise direction 11.

The opaque materials 16 separate the thin film photoelectric conversion cells 12 into a plurality of sub-arrays 120, wherein in each of the sub-arrays 120, the plurality of thin film photoelectric conversion cells 12 are connected in series along the traversing direction 13.

Each of the opaque materials 16 is made of metal, paint, non-transparent glass, ceramics, non-transparent plastic or other reflecting and absorbing material to shade from the sunlight. Accordingly, the light projects to the ribbon-like region of the thin film photoelectric conversion cells 12 under the opaque materials 16 is entirely intercepted by the opaque materials 16. Due to the high resistance generated by the intercepted region, each of the thin film photoelectric conversion cells 12 is separated into a plurality of sections each belongs to one of the sub-arrays 120. Therefore, the thin film photoelectric conversion cells 12 are separated into the sub-arrays 120 having the cells 12 connected in serial. Consequently, when the thin film photoelectric conversion module 1 operates normally, the thin film photoelectric conversion module 1 is separated into a plurality of sub-arrays 120.

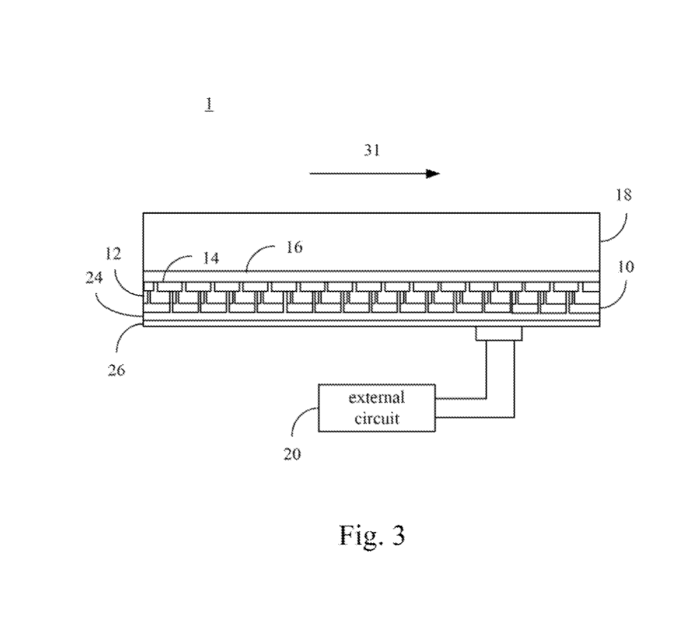

Please refer to FIG. 3. FIG. 3 is another side view of the thin film photoelectric conversion module 1 from the direction B in FIG. 1. Since the thin film photoelectric conversion cells 12 are connected in series, when the thin film photoelectric conversion cells 12 receives the sunlight and when the front electrode layer 14 and the back electrode layer 10 are connected to an external circuit 20, the current generated according to the sunlight flows from a positive end to a negative end along the direction 31 as depicted in FIG. 3 to covert the solar energy into electrical power. The sunlight is able to traverse the transparent substrate 18 and the front electrode layer 14 since they are both transparent. Further, if the back electrode layer 10 is made of metal that is not transparent, the back electrode layer 10 is able to reflect the sunlight that passes through the thin film photoelectric conversion cells 12 back to the thin film photoelectric conversion cells 12 to raise the efficiency of the thin film photoelectric conversion module 1.

In different embodiments, these sub-arrays 120 can work separately or can be connected together, whether in series or in parallel, to convert the energy of received sunlight directly into an electrical power by the photovoltaic effect. Please refer to FIG. 2 and FIG. 3 at the same time. In an embodiment, the thin film photoelectric conversion module 1 further comprises a junction box 22 connected to the back electrode layer 10. In practical application, the thin film photoelectric conversion module 1 further comprises an encapsulation material 24, such as EVA (ethylene vinyl acetate), and a second substrate 26 for protection, such as a back sheet laminate or a transparent substrate, which are disposed subsequently between the back electrode layer 10 and the junction box 22. The electrical power generated from the thin film photoelectric conversion cells 12 is transmitted to the external circuit 20 through the junction box.

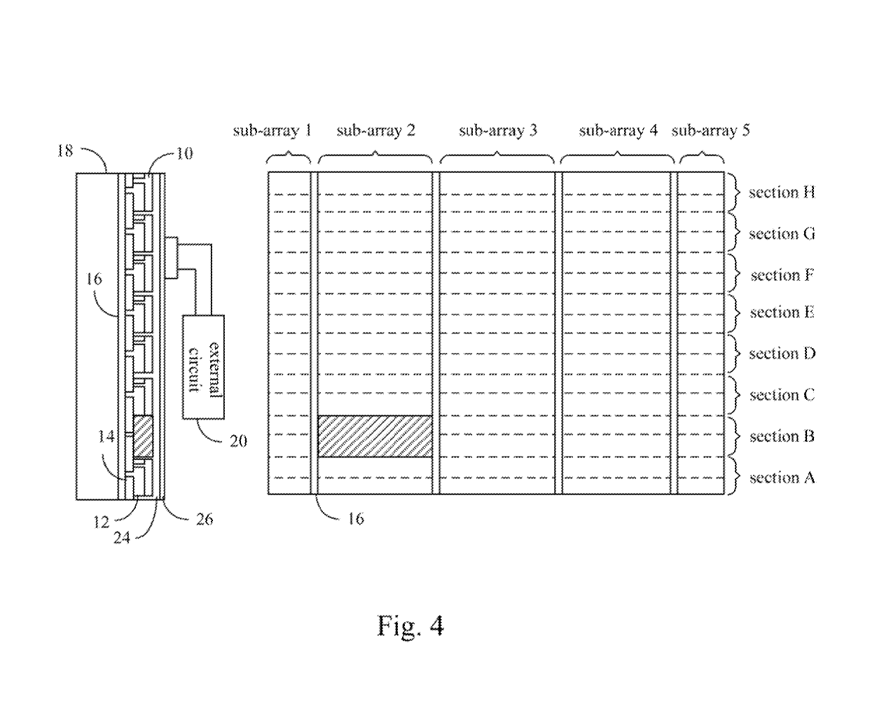

When an undesired object, such as a leaf or a bird dropping, is attached to the thin film photoelectric conversion module 1, the hot spot phenomenon is generated on the region where the undesired object locates. Please refer to FIG. 4. FIG. 4 is a diagram of both the top view and the side view of the thin film photoelectric conversion module 1 in FIG. 1 and FIG. 3. The thin film photoelectric conversion cells 12 in FIG. 1 are divided into five sub-arrays and eight sections labeled as sub-array 1 to sub-array 5 and section A to section H in FIG. 4. If the area B2 is intercepted by an undesired object, the hot spot phenomenon is generated. If a laser-scribing technique is used to separate both the electrode 14, 10 and the thin film photoelectric conversion cells 12, the current in the whole sub-array 2 (i.e. the remaining area A2, C2, D2, E2, F2, G2 and H2) can't flow to other places and will generate a lot of heat due to the high resistance area B2. The whole sub-array 2 is not able to operate as normal, and the efficiency of the thin film photoelectric conversion module 1 degrades.

However, in the present embodiment, the front electrode layer 14 and the back electrode layer 10 are not separated. As a result, though the thin film photoelectric conversion cells 12 within each sub-array are separated, the front electrode layer 14 and the back electrode layer 10 are still able to connect different sub-arrays. If the area B2 is intercepted by an undesired object, the current from the remaining area A2, C2, D2, E2, F2, G2 and H2 is able to flow to other areas with much lower resistance, e.g. B1 and B3. Thus, except the area B2, the other areas in sub-array 2 are still able to generate the current according to the sunlight without dissipating the current in the area B2. Therefore, only the area B2 intercepted by the undesired object is not able to operate as normal. The thin film photoelectric conversion module 1 can still maintain a high efficiency when the hot spot phenomenon occurs.

In an experimental result, when a conventional thin film photoelectric conversion module with the illumination power of 1 KW/m² is intercepted by an undesirable object with 25×45 cm², the power degrades from the original 100 W to 70 W. The power reduction rate is about 30%. When a thin film photoelectric conversion module of the present disclosure is used under the same situation, the power degrades from the original 117 W to 93 W. The power reduction rate is only about 20%, which is much better than the power reduction rate when the conventional thin film photoelectric conversion module is used.

It's noticed that in other embodiments, the opaque materials can be replaced by a plurality of semi-transparent materials having a non-transmission rate over 80% to accomplish a similar effect.

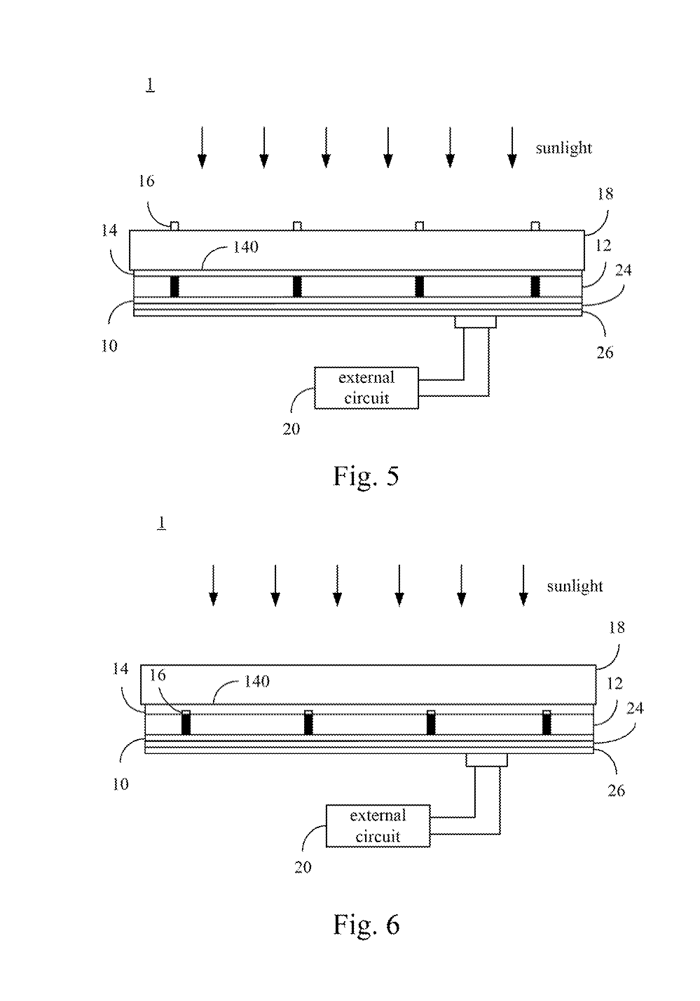

Please refer to FIG. 5. FIG. 5 is a side view of the thin film photoelectric conversion module 1 from the direction A in FIG. 1 in another embodiment of the present disclosure. In the present embodiment, the transparent substrate 18 is disposed on the light-receiving surface 140 directly, whereas the opaque materials 16 are substantially disposed on the transparent substrate 18. Nevertheless, though the opaque materials 16 are able to intercept the sunlight to separate the thin film photoelectric conversion cells 12 into a plurality of sub-arrays to accomplish the effect as in FIG. 2, the distance between the opaque materials 16 and the light-receiving surface 140 of the front electrode layer 14 (i.e. the height of the transparent substrate 18) may generate an undesirable consequence. The interception may not be complete or the position of the edge between each of two sub-arrays may be different due to the distance mentioned above. Therefore, the arrangement of the opaque materials 16 that are disposed directly on the light-receiving surface 140 of the front electrode layer 14 as depicted in FIG. 2 is still preferred.

Please refer to FIG. 6. FIG. 6 is a side view of the thin film photoelectric conversion module 1 from the direction A in FIG. 1 in yet another embodiment of the present disclosure. In the present embodiment, the opaque materials 16 (or semi-transparent materials) each disposed between the front electrode layer and the thin film photoelectric conversion cells traversing the plurality of thin film photoelectric conversion cells in a traversing direction substantially vertical to the lengthwise direction to separate the plurality of thin film photoelectric conversion cells into a plurality of sub-arrays.

The present disclosure provides a thin film photoelectric conversion module that is able to lower the impact of the hot spot phenomenon without massively degrading the efficiency of the thin film photoelectric conversion cells.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A thin film photoelectric conversion module, comprising:
a back electrode layer;
a plurality of thin film photoelectric conversion cells disposed on the back electrode layer in parallel to each other in a lengthwise direction;
a front electrode layer disposed on the plurality of thin film photoelectric conversion cells, wherein the front electrode layer has a light-receiving surface; and
a plurality of opaque materials each disposed on the light-receiving surface traversing the plurality of thin film photoelectric conversion cells in a traversing direction substantially vertical to the lengthwise direction to separate the plurality of thin film photoelectric conversion cells into a plurality of sub-arrays, wherein in each of the plurality of sub-arrays, the plurality of thin film photoelectric conversion cells are connected in series along the traversing direction.

2. The thin film photoelectric conversion module of claim 1, further comprises a transparent substrate disposed on the light-receiving surface, wherein the plurality of opaque materials are substantially disposed between the transparent substrate and the light-receiving surface.

3. The thin film photoelectric conversion module of claim 2, further comprising an encapsulation layer and a second substrate disposed subsequently under the back electrode layer.

4. The thin film photoelectric conversion module of claim 3, wherein the second substrate comprise a transparent substrate or a back sheet laminate.

5. The thin film photoelectric conversion module of claim 1, further comprises a transparent substrate disposed on the light-receiving surface, wherein the plurality of opaque materials are substantially disposed on a surface of the transparent substrate opposite to the light-receiving surface.

6. The thin film photoelectric conversion module of claim 5, further comprising an encapsulation layer and a second substrate disposed subsequently under the back electrode layer.

7. The thin film photoelectric conversion module of claim 6, wherein the second substrate comprise a transparent substrate or a back sheet laminate.

8. The thin film photoelectric conversion module of claim 1, wherein each of the plurality of opaque materials is a ribbon-like material.

9. The thin film photoelectric conversion module of claim 1, wherein each of the plurality of opaque materials is made of metal, paint, non-transparent glass, ceramics, non-transparent plastic or other reflecting and absorbing materials.

10. The thin film photoelectric conversion module of claim 1, wherein the front electrode layer is a transparent conducting layer.

11. The thin film photoelectric conversion module of claim 1, wherein the back electrode layer is a transparent conducting layer or a metal layer.

12. The thin film photoelectric conversion module of claim 1, wherein each of the plurality of thin film photoelectric conversion cells comprises a P-I-N structure.

13. The thin film photoelectric conversion module of claim 12, wherein the front electrode layer is a positive electrode and the back electrode layer is a negative electrode.

14. The thin film photoelectric conversion module of claim 1, wherein each of the plurality of thin film photoelectric conversion cells in each of the plurality of sub-arrays converts a solar energy into an electrical power and transmit the electrical power to an external circuit through the front electrode layer and the back electrode layer.

15. The thin film photoelectric conversion module of claim 14, further comprising a junction box connected to the front electrode layer and the back electrode layer to transmit the electrical power to the external circuit.

16. A thin film photoelectric conversion module, comprising:
a back electrode layer;
a plurality of thin film photoelectric conversion cells disposed on the back electrode layer in parallel to each other in a lengthwise direction;
a front electrode layer disposed on the plurality of thin film photoelectric conversion cells, wherein the front electrode layer has a light-receiving surface; and
a plurality of semi-transparent materials each disposed on the light-receiving surface traversing the plurality of thin film photoelectric conversion cells in a traversing direction substantially vertical to the lengthwise direction to separate the plurality of thin film photoelectric conversion cells into a plurality of sub-arrays, wherein in each of the plurality of sub-arrays, the plurality of thin film photoelectric conversion cells are connected in series along the traversing direction.

17. The thin film photoelectric conversion module of claim 16, wherein the non-transmission rate of the semi-transparent materials is over 80%.

18. A thin film photoelectric conversion module, comprising:
a back electrode layer;
a plurality of thin film photoelectric conversion cells disposed on the back electrode layer in parallel to each other in a lengthwise direction;
a front electrode layer disposed on the plurality of thin film photoelectric conversion cells, wherein the front electrode layer has a light-receiving surface; and
a plurality of opaque materials or semi-transparent materials each disposed between the front electrode layer and the thin film photoelectric conversion cells traversing the plurality of thin film photoelectric conversion cells in a traversing direction substantially vertical to the lengthwise direction to separate the plurality of thin film photoelectric conversion cells into a plurality of sub-arrays, wherein in each of the plurality of sub-arrays, the plurality of thin film photoelectric conversion cells are connected in series along the traversing direction.
